(19) United States
(12) Patent Application Publication
(10) Pub. No.: US 2008/0245415 A1
(43) Pub. Date: Oct. 9, 2008

(54) PHOTOELECTRIC CONVERSION DEVICE AND FABRICATION METHOD THEREOF

(76) Inventors: Hwa Nyeon Kim, Seoul (KR); Bum Sung Kim, Seoul (KR); Hae Seok Lee, Seoul (KR); Jung Heum Yun, Seoul (KR); Heon Min Lee, Seoul (KR)

Correspondence Address: BIRCH STEWART KOLASCH & BIRCH, PO BOX 747, FALLS CHURCH, VA, 22040-0747, US

(21) Appl. No.: 12/098,276

(22) Filed: Apr. 4, 2008

(30) Foreign Application Priority Data
Apr. 9, 2007 (KR) 10-2007-0034787

(51) Int. Cl. H01L 31/0264; H01L 31/0376; H01L 31/18

(52) U.S. Cl. 136/261; 136/252; 136/262; 438/96; 257/E31.004; 257/E31.047

(57) ABSTRACT

A photoelectric conversion device includes at least one p-type semiconductor layer made of amorphous like hydrogenated carbon film or diamond like carbon (DLC) film doped with acceptor impurities such as boron (B). In a solar cell having a photoelectric conversion region, hydrogenated carbon is used as substances forming a p-type semiconductor layer, making it possible to provide a solar cell with high photoelectric conversion efficiency.

### BACKGROUND OF THE INVENTION

This application claims priority to Korean Patent Application No. 10-2007-0034787, filed on Apr. 9, 2007, in the Korean Intellectual Property Office, the entire contents of which are hereby incorporated by reference.

1. Field of the Invention

The present invention relates to a photoelectric conversion device and a fabrication method thereof, and more specifically to a photoelectric conversion device and a fabrication method thereof using amorphous like hydrogenated carbon film or diamond like carbon (DLC) film doped with acceptor impurities such as boron (B) as substances forming a p-type semiconductor layer, in a solar cell having a photoelectric converting region.

2. Description of the Prior Art

A study on photovoltaic power generation as a next-generation clean energy source has actively been progressed since it does not cause environmental disruption by using new renewable energy and can obtain energy anywhere.

A silicon single crystal solar cell currently widely commercialized for photovoltaic power generation is high in fabricating costs due to use of an expensive wafer, as such its use is restricted.

In order to develop a solar cell that can solve the above problem, dramatically reduce the costs of raw substances, and obtain high efficiency and high reliability, various attempts have been proposed and studied.

Recently, research and development for a solar cell wherein substances based on amorphous silicon are deposited on plate-shape glass or metal in a multi-layer form is actively progressing. It has a disadvantage of relatively low photoelectric conversion efficiency as compared to a crystalline silicon solar cell; however, it has many advantages, such as, the photoelectric conversion efficiency can be improved according to the substances to be deposited and through the multi-layer cell structure, a large area solar cell module can be fabricated at low costs, and an energy recovery period is short.

In particular, if fabrication speed is fast by use of large and automated deposition equipment, fabricating costs of a large area substrate-type solar cell can be further reduced. As a result, study thereinto has been actively progressing.

FIG. 1 is a cross-sectional view schematically showing a stacked structure of a solar cell according to one example of the prior art. In other words, FIG. 1 is a cross-sectional view schematically showing a stacked structure of a silicon-based solar cell of the prior art, generally called a single junction cell.

Referring to FIG. 1, prominences and depressions are made by performing surface treatment on a transparent conductive oxide. (TCO) layer 101 coated on a glass substrate 100 and a semiconductor layer configured of p-i-n types 102, 103, and 104 using silicon-based substances is stacked on the transparent conductive oxide layer 101.

The semiconductor layer of the aforementioned example configured of the p-type, the i-type, and the n-type is divided into a one junction cell. In other words, only a one junction cell deposited on a substrate is defined as the single junction cell.

If necessary, an intermediate layer such as a buffer layer buffering a sudden difference in band gaps may be formed between the p-type semiconductor layer and the i-type semiconductor layer.

After stacking the junction cell on the substrate, each of a transparent conductive oxide layer 105 and an electrode layer 106 is further stacked on the semiconductor layer.

FIG. 2 is a cross-sectional view schematically showing a stacked structure of a photoelectric conversion device according to another example of the prior art. FIG. 2 shows a structure of a tandem-type solar cell particularly including a double semiconductor layer.

Referring to FIG. 2, a double junction cell, among the silicon-based solar cells, known as a tandem cell, is stacked on a transparent conductive oxide layer 201 formed on a glass substrate 200. To describe more specifically, prominences and depressions are made by performing surface treatment on the transparent conductive oxide layer 201 formed on the glass substrate 200 and semiconductor layers consisting of silicon-based substances are doubly stacked on the transparent conductive oxide layer 201.

As described above, the junction cell of the solar cell uses a p-type semiconductor layer 202, an i-type semiconductor layer 203, and an n-type semiconductor layer 204 as one unit. The above example of the prior art describes a case where the semiconductor layers are doubly stacked. In other words, since the semiconductor layer is configured by a stack of a p-type 2022, an i-type 2032, and an n-type 2042 of a second semiconductor layer on a p-type 2021, an i-type 2031, and an n-type 2041 of a first semiconductor layer, the semiconductor layer is referred to as a double junction cell.

If necessary, an intermediate layer such as a buffer layer buffering a sudden difference in band gaps may be formed between the p-type semiconductor layer and the i-type semiconductor layer and an intermediate layer may be formed between two junction cells for the solar cell.

Further, a transparent conductive oxide layer 205 and an electrode layer is deposited on the second semiconductor layer, respectively.

With the same principle, it is possible to fabricate a solar cell with a tandem structure of a triple junction cell that is configured by a stack of three semiconductor layers, that is, three junction cells.

The p-type semiconductor layer and the n-type semiconductor layer among the junction cells for the solar cell are impurity semiconductor layers doped with acceptor impurities and donor impurities, respectively. In particular, as substances mainly used for forming the p-type semiconductor layer, there are hydrogenated amorphous silicon (a-Si:H) doped with group III elements or microcrystalline silicon (mc-Si:H). Of the group III elements, boron (B) has mainly been used.

Recently, hydrogenated amorphous silicon carbide (a-SiC:H) doped with boron (B) which has a higher band gap energy (Eg) than these substances or hydrogenated microcrystalline silicon carbide (mc-SiC:H) doped with boron (B) are used as substances forming the p-type semiconductor layer, thereby contributing to an improvement of efficiency of the solar cell.

However, in order to develop the solar cell with higher photoelectric conversion efficiency and reliability, there is a need for more study on substances with high band gap energy (Eg) and on a method of applying these substances to the p-type semiconductor layer.

### SUMMARY OF THE INVENTION

The present invention proposes to solve a problem of efficiency of substances forming a semiconductor layer of a conventional solar cell. It is an object of the present invention to provide a solar cell wherein substances such as hydrogenated carbon film or diamond like carbon film with high band gap energy are applied to a p-type semiconductor layer.

Also, it is an object of the present invention to provide a fabrication method of a solar cell capable of simply and effectively solving a problem of photoelectric conversion efficiency of a conventional solar cell by changing substances forming a p-type semiconductor in a fabrication process of a conventional solar cell, without adding separate processes.

In order to achieve the objects, there is provided a photoelectric conversion device comprising a substrate; and at least one photoelectric conversion layer formed on a substrate, wherein the photoelectric conversion layer includes a p-type semiconductor layer made of hydrogenated carbon film doped with impurities or diamond like carbon (DLC) film doped with impurities.

The photoelectric conversion layer of the present invention, which is formed by a stack of at least one semiconductor layer, is a layer that can receive light and then convert it into electrical energy.

The plurality of photoelectric conversion layers may be formed in a single junction, a double junction, or a triple junction.

In the present invention, a state of hydrogenated carbon may be selected from a group consisting of an amorphous state, a crystalline state, a micro-sized microcrystalline state, a nano-sized microcrystalline state, and a mixed state thereof and the diamond like carbon is generally formed in an amorphous state.

In the present invention, the micro-sized microcrystalline means that a microcrystalline grain size is a unit of several to several hundreds of micrometers (μm) and the nano-sized microcrystalline means that its grain size is a unit of several to several hundreds of nanometers (nm).

Preferably, the impurities are group III elements, and in particular, may be any one of boron (B), aluminum (Al), gallium (Ga), and indium (In).

Preferably, the photoelectric conversion device of the present invention further comprises a buffer layer made of hydrogenated silicon carbide formed on the p-type semiconductor layer.

A state of the buffer layer may be selected from a group consisting of an amorphous state, a crystalline state, a micro-sized microcrystalline state, a nano-sized microcrystalline state, and a mixed state thereof, but the present invention is not particularly limited thereto.

Also, as the substrate of the present invention, a glass substrate, a metal substrate, a metal foil and a transparent polymer, etc. may be used.

A photoelectric conversion layer of the present invention may be configured of at least one semiconductor layer and preferably be configured of a p-type semiconductor layer made of hydrogenated carbon film doped with impurities or diamond like carbon (DLC) film doped with impurities, and an n-type semiconductor layer made of hydrogenated silicon or i-type and n-type semiconductor layers made of hydrogenated silicon sequentially formed on the p-type semiconductor layer.

Further, in order to achieve the object, there is provided a fabrication method of a photoelectric conversion device of the present invention comprising the steps of: a) forming at least one photoelectric conversion layer including a p-type semiconductor layer made of hydrogenated carbon film doped with any one of group III elements or diamond like carbon (DLC) film doped with any one of group III elements, on a transparent conductive oxide layer formed on a substrate; and b) forming a metal electrode layer on the photoelectric conversion layer.

The photoelectric conversion layer includes a p-type semiconductor layer, and an n-type semiconductor layer made of hydrogenated silicon or i-type and n-type semiconductor layers made of hydrogenated silicon sequentially formed on the p-type semiconductor layer.

In other words, the present invention provides a fabrication method of a photoelectric conversion device that forms a p-type semiconductor layer made of hydrogenated carbon film doped with any one of group III elements such as boron (B), aluminum (Al), gallium (Ga), and indium (In), etc. or diamond like carbon (DLC) film doped with any one of group III elements, boron (B), aluminum (Al), gallium (Ga), and indium (In), etc. after forming a transparent conductive oxide layer on a substrate, and then sequentially stacks an n-type semiconductor layer made of silicon or silicon carbide, a transparent conductive oxide layer and a metal electrode layer on the p-type semiconductor layer.

Meanwhile, the p-type semiconductor layer may be sequentially stacked with an i-type semiconductor layer made of silicon or silicon carbide, an n-type semiconductor layer made of silicon or silicon carbide, a transparent conductive oxide layer, and a metal electrode layer.

At least one photoelectric conversion layer formed as above may be formed in a single junction, a double junction, or a triple junction on the substrate.

Also, after forming the p-type semiconductor layer, the fabrication method of the present invention further comprises the step of forming a buffer layer made of hydrogenated silicon carbide on the p-type semiconductor layer.

A state of the buffer layer may be selected from any one of a group consisting of an amorphous state, a crystalline state, a micro-sized microcrystalline state, a nano-sized microcrystalline state, and a mixed state thereof.

According to one embodiment of the present invention, the p-type semiconductor layer is made of hydrogenated amorphous carbon (a-C:H) doped with boron (B) or hydrogenated microcrystalline carbon (mc-C:H) doped with boron (B).

In general, an i-type semiconductor layer or an n-type semiconductor layer is stacked on a p-type semiconductor layer of a solar cell, wherein if the i-type semiconductor layer or the n-type semiconductor layer are made of silicon, a difference in band gap energy may be great enough that a buffer layer to provide a buffering effect may be further included.

The buffer layer is made of hydrogenated amorphous silicon carbide (a-SiC:H) or hydrogenated microcrystalline silicon carbide (mc-SiC:H).

When the cell including the p-type semiconductor layer including other formation substances and the i-type and n-type semiconductor layers is one basic junction cell, at least one junction cell may be stacked.

In other words, the solar cell comprising any one of a single junction cell, a double junction cell, a triple junction cell, and a multi-junction cell including the p-type semiconductor layer made of the hydrogenated carbon film or the diamond like carbon (DLC) film may be provided.

In the present invention, the hydrogenated carbon is referred to as compounds wherein at least one hydrogen is coupled to each carbon atom, and the diamond like carbon (DLC) film, which is a representative substance of a thin film of carbon composition, is referred to as an amorphous substance consisting of carbon wherein quadratic coupling of diamond and hexagonal coupling of graphite are mixed.

The DLC film can be physically controlled so that the excellent physical and mechanical properties of diamond are well harmonized with the excellent electrical properties of graphite by controlling a coupling amount of diamond and graphite.

The method according to one embodiment of the present invention fabricates the p-type semiconductor layer by means of doping boron (B) into the diamond like carbon film so that the solar cell with higher photoelectric conversion efficiency can be provided by making a band gap energy excellent as compared to the semiconductor layer made of the conventional substance.

### BRIEF DESCRIPTION OF THE DRAWINGS

These and other objects, features, and advantages of preferred embodiments of the present invention will be more fully described in the following detailed description, taken in conjunction with the accompanying drawings. In the drawings:

FIG. 1 is a cross-sectional view schematically showing a stacked structure of a photoelectric conversion device according to one example of the prior art;

FIG. 2 is a cross-sectional view schematically showing a stacked structure of a tandem-type photoelectric conversion device according to another example of the prior art;

FIG. 3 is a cross-sectional view schematically showing a stacked structure of a photoelectric conversion device according to one embodiment of the present invention;

FIG. 4 is an enlarged view showing an amorphous state of a p-type semiconductor layer of the photoelectric conversion device according to one embodiment of the present invention;

FIG. 5 is an enlarged view showing a mixed state of amorphous and crystalline states of the p-type semiconductor layer of the photoelectric conversion device according to one embodiment of the present invention; and

FIG. 6 is a cross-sectional view schematically showing the stacked structure of a photoelectric conversion device including a buffer layer according to another embodiment of the present invention.

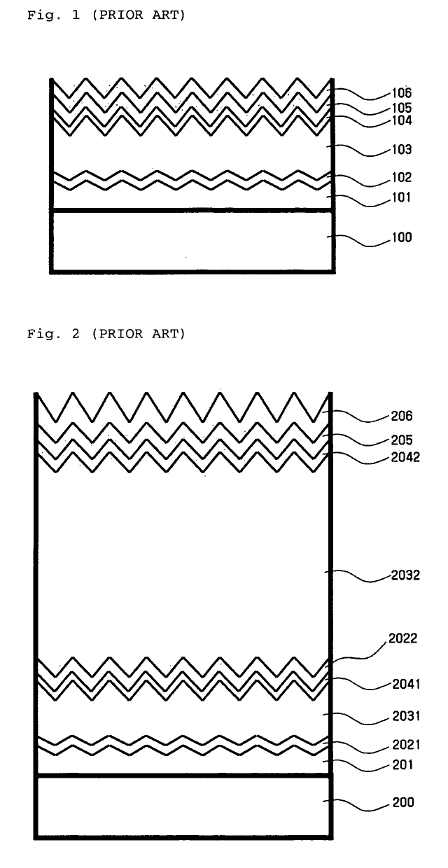

### DESCRIPTION OF THE PREFERRED EMBODIMENTS

Embodiments of the present invention will now be described hereafter with reference to the attached drawings. Reference numerals added to construction elements of each drawings use the same numerals within the range of the same construction elements, even though they are indicated in the other drawings, and the detailed description about well-known functions and structures, which are outside the subject matter of the present invention will be omitted.

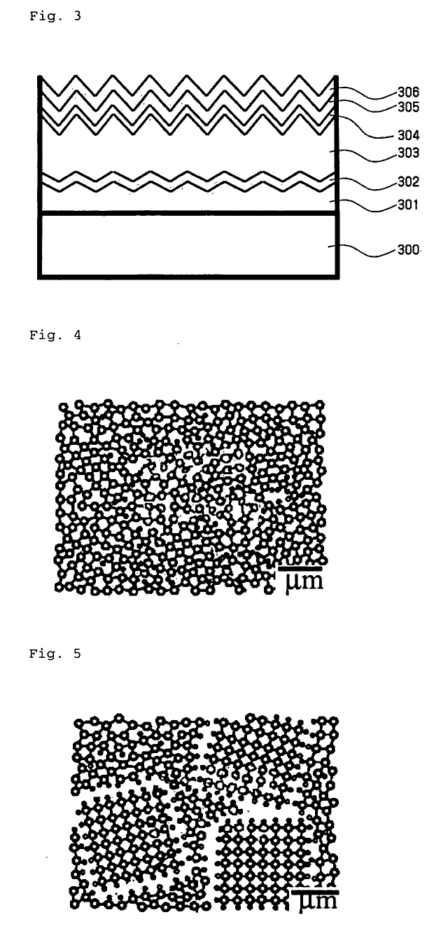

FIG. 3 is a cross-sectional view schematically showing a stacked structure of a photoelectric conversion device according to one embodiment of the present invention.

Referring to FIG. 3, there is shown a photoelectric conversion device wherein a p-type semiconductor layer 302 is formed on a transparent conductive oxide layer 301 stacked on a substrate 300.

The p-type semiconductor layer 302 is made of hydrogenated amorphous carbon (a-C:H) film doped with boron (B) or diamond like carbon (DLC) film doped with boron (B).

An i-type semiconductor layer 303 and an n-type semiconductor layer 304 of a solar cell using hydrogenated amorphous silicon (a-Si:H) as formation substances are stacked on the p-type semiconductor layer 302.

The transparent conductive oxide layer 305 and a metal electrode layer 306 are sequentially stacked on the semiconductor layer. However, the solar cell is not limited to such a stacked structure, but it can be formed as a tandem-type solar cell wherein the p-i-n type semiconductor layers including the p-type semiconductor layer are stacked in double, triple, and multiple layers and the metal electrode layer is stacked thereon.

Band gap energy of the hydrogenated carbon (a-C:H), which is the formation substance of the p-type semiconductor layer, is 1.8 to 2.8 eV. Such a band gap energy is higher than band gap energy (1.7 eV) of hydrogenated amorphous silicon (a-Si:H) and band gap energy (2.0 eV) of hydrogenated amorphous silicon carbide (a-SiC:H) that are applied to the p-type semiconductor of the existing solar cell, making it possible to remarkably improve the photoelectric conversion efficiency of the solar cell.

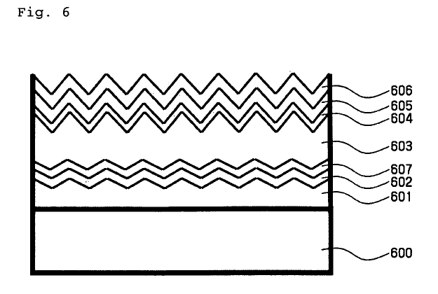

FIGS. 4 and 5 are enlarged views showing a mixed state of amorphous and crystalline states of the p-type semiconductor layer of the photoelectric conversion device according to one embodiment of the present invention, respectively.

According to one embodiment of the present invention, the p-type semiconductor layer is made of hydrogenated carbon film doped with boron (B) or the diamond like carbon film, wherein the state may be an amorphous state, a crystalline state, a microcrystalline state, and a mixed state thereof.

FIG. 4 shows an amorphous state with irregular structure due to a breakage of regularity of crystal lattices of carbon particles of the p-type semiconductor layer by hydrogenation.

Referring to FIG. 5, it can be appreciated that the hydrogenated carbon particles of the p-type semiconductor layer have a mixed intermediate form of the crystalline state and the amorphous state.

The formation substances forming the p-type semiconductor layer of the photoelectric conversion device according to one embodiment of the present invention are: the hydrogenated carbon that can be variously formed in the crystalline state, the amorphous state, the microcrystalline state, or a mixed state thereof unlike silicon or silicon carbide in the amorphous form; or the DLC of carbon composition with properties similar to the diamond state so that the band gap energy is high, making it possible to provide a solar cell with high photoelectric efficiency.

FIG. 6 is a cross-sectional view schematically showing the stacked structure of a photoelectric conversion device including a buffer layer according to another embodiment of the present invention.

Referring to FIG. 6, a p-type semiconductor layer 602 is formed on a transparent conductive oxide layer 601 stacked on a substrate 600, wherein the formation substance is hydrogenated amorphous carbon doped with boron (B). A buffer layer 607 is formed at an interface between a p-type semiconductor layer 602 and an i-type semiconductor layer 603 before stacking the i-type semiconductor layer 603 and an n-type semiconductor layer 604 of the hydrogenated amorphous silicon (a-Si:H) as the formation substance on the p-type semiconductor layer 602.

The buffer layer 607 uses the hydrogenated silicon carbide (SiC:H) as the formation substance, wherein the state may be an amorphous state, a crystalline state, a microcrystalline state, and a mixed state thereof, but the present invention is not limited thereto.

The buffer layer can mitigate a sudden difference in band gaps when the difference in energy band gaps between the hydrogenated amorphous carbon (a-C:H) that is the formation substance of the p-type semiconductor layer and the hydrogenated amorphous silicon (a-Si:H) that is the formation substance of the i-type semiconductor layer of the present invention is too large.

The technology of using the DLC thin film doped with boron (B) according to the present embodiment for the p-type semiconductor layer can be applied to a double junction solar cell and triple junction solar cell.

The technology can be applied to the p-type semiconductor layer of at least one solar cell.

In the solar cell including the double or triple solar cell, when the p-type semiconductor layer is included in the bottom solar cell, it can be relatively less affected by the sunlight absorbance of the upper solar cell first absorbing sunlight due to an influence of the high band gap energy.

Therefore, it contributes to an increase of power generation of the lower solar cell formed on the lower portion of the upper solar cell so that the efficiency of the overall solar cell is improved.

As the substrate on which the p-type semiconductor layer according to one embodiment of the present invention is applied, substrates that can be used for plasma deposition equipment are suitable. In particular, as the substrate, a glass plate, a metal plate, a metal foil, and a transparent polymer, etc. can be used. Therefore, it can be expected that the present invention can be applied to various solar cells so that its application range can be expanded and it can be widely used.

With the present invention as described above, the substances such as the hydrogenated carbon film or the diamond like carbon film with the high band gap energy are applied to the p-type semiconductor layer, making it possible to provide a photoelectric conversion device with high efficiency and high reliability.

Also, in the solar cell including the multiple solar cells, at least one p-type semiconductor layer of the present invention is applied to increase the absorbance of sunlight and power generation.

Consequently, the substances used for the p-type semiconductor layer are changed so as to be applied to various photoelectric conversion devices and expand their application range, making it possible to improve the economic value of solar cells.

Although the present invention has been described in detail reference to its presently preferred embodiment, it will be understood by those skilled in the art that various modifications and equivalents can be made without departing from the spirit and scope of the present invention, as set forth in the appended claims.

What is claimed is:

1. A photoelectric conversion device comprising:
a substrate; and
at least one photoelectric conversion layer formed on the substrate, wherein the photoelectric conversion layer includes a p-type semiconductor layer made of hydrogenated carbon film doped with impurities or diamond like carbon (DLC) film doped with impurities

2. The device according to claim 1, wherein a state of the hydrogenated carbon film is any one state selected from a group consisting of an amorphous state, a crystalline state, a micro-sized microcrystalline state, a nano-sized microcrystalline state, and a mixed state thereof.

3. The device according to claim 1, wherein the impurities are selected from elements of a group III.

4. The device according to claim 3, wherein the group III elements are consisting of boron (B), aluminum (Al), gallium (Ga), and indium (In).

5. The device according to claim 1, further comprising a buffer layer made of hydrogenated silicon carbide formed on the p-type semiconductor layer.

6. The device according to claim 5, wherein a state of the buffer layer is any one state selected from a group consisting of an amorphous state, a crystalline state, a micro-sized microcrystalline state, a nano-sized microcrystalline state, and a mixed state thereof.

7. The device according to claim 1, wherein the substrate is any one substrate selected from a group consisting of a glass substrate, a metal substrate, a metal foil and a transparent polymer.

8. The device according to claim 1, wherein the photoelectric conversion layer comprises:
the p-type semiconductor layer; and
an n-type semiconductor layer made of hydrogenated silicon or i-type and n-type semiconductor layers made of hydrogenated silicon sequentially formed on the p-type semiconductor layer.

9. A fabrication method of a photoelectric conversion device comprising the steps of:
a) forming at least one photoelectric conversion layer including a p-type semiconductor layer made of hydrogenated carbon film doped with any one of group III elements or diamond like carbon (DLC) film doped with any one of group III elements, on a transparent conductive oxide layer formed on a substrate; and
b) forming a metal electrode layer on the photoelectric conversion layer.

10. The method according to claim 9, wherein the photoelectric conversion layer comprises:
the p-type semiconductor layer; and
an n-type semiconductor layer made of hydrogenated silicon or i-type and n-type semiconductor layers made of hydrogenated silicon sequentially formed on the p-type semiconductor layer.

11. The method according to claim 10, further comprising the step of forming a buffer layer made of hydrogenated silicon carbide on the p-type semiconductor layer.

12. The method according to claim 11, wherein the buffer layer is formed in any one state selected from a group consisting of an amorphous state, a crystalline state, a micro-sized microcrystalline state, a nano-sized microcrystalline state, and a mixed state thereof.

13. The method according to claim 9, wherein a state of hydrogenated carbon film is any one state selected from a group consisting of an amorphous state, a crystalline state, a micro-sized microcrystalline state, a nano-sized microcrystalline state, and a mixed state thereof.

14. The method according to claim 9, wherein the group III elements are consisting of boron (B), aluminum (Al), gallium (Ga), and indium (In).
